(19) United States
(12) Patent Application Publication
(10) Pub. No.: US 2024/0217230 A1
(43) Pub. Date: Jul. 4, 2024

(54) INKJET PRINTING SYSTEM

(71) Applicant: Shenzhen China Star Optoelectronics Semiconductor Display Technology Co., Ltd., Shenzhen (CN)

(72) Inventor: Can PENG, Shenzhen (CN)

(73) Assignee: Shenzhen China Star Optoelectronics Semiconductor Display Technology Co., Ltd., Shenzhen (CN)

(21) Appl. No.: 18/398,211

(22) Filed: Dec. 28, 2023

(30) Foreign Application Priority Data
Dec. 30, 2022 (CN) 202211739912.1

(51) Int. Cl. B41J 2/045; B41J 2/14; H10K 59/122; H10K 59/65

(52) U.S. Cl. CPC B41J 2/04501; B41J 2/14; H10K 59/122; H10K 59/65

(57) ABSTRACT

An inkjet printing system is disclosed in the present disclosure. The inkjet printing system includes: an inkjet printing device with nozzles having pixel ink, a display substrate including a display region and an under-screen camera region, and an ink droplet flow rate control device connected to the nozzles. The nozzles are arranged above the display substrate. The display substrate includes a base, and a pixel defining layer on a surface of the base. The pixel defining layer is disposed with first pixel openings in the display region, and second pixel openings in the under-screen camera region. The first pixel opening has a greater opening area than the second pixel opening. The ink droplet flow rate control device is used to respectively control ink droplet outflow rates of pixel ink of the nozzles corresponding to the display region and the under-screen camera region.

### CROSS-REFERENCE TO RELATED APPLICATION

This application claims priority to Chinese Patent Application No. 202211739912.1, filed on Dec. 30, 2022, the disclosure of which is incorporated herein by reference in its entirety.

### TECHNICAL FIELD

The present disclosure relates to the field of inkjet printing technologies, and in particular, to an inkjet printing system.

### BACKGROUND

At present, organic light-emitting diodes (OLEDs) are gradually expanding their market influence owing to their special performances such as low power consumption, fast response speed, high contrast, wide color gamut, thinner than LCDs, and flexible display. An inkjet printing (IJP) OLED is a new preparation process for OLED, compared with a traditional evaporation process, the inkjet printing OLED carries out printing according to needs of organic materials, which can achieve a material utilization more than 90%. The inkjet printing OLED does not need to be carried out in vacuum, and high-precision printing can be achieved by controlling the accuracy of nozzle.

Current under-screen camera technology mainly relies on reducing a pixel opening, allowing more lights to enter a camera module to achieve effective imaging. At present, a side by side (SBS) architecture is often used for pixel arrangement, and inkjet printing of the SBS architecture needs to print an integer number of ink droplets in a pixel to achieve an expected film thickness. For pixels with the SBS architecture, in case of the under-screen camera technology being realized by changing the pixel opening size, it is necessary to ensure that an opening area of a R/G/B main pixel to an opening area of a R/G/B sub-pixel is in a fixed ratio, and the ratio must satisfy that: S_Main/S_Sub=Drop_Main/Drop_Sub (where S_Main represents the opening area of the main pixel, S_Sub represents the opening area of the sub-pixel, Drop_Main represents the number of ink droplets for the main pixel, and Drop_Sub represents the number of ink droplets for the sub-pixel). In such way, it can be ensured that a film thickness of the main pixel is equivalent to a film thickness of the sub-pixel. Moreover, while the pixel with the SBS architecture is reduced in size, the number of usable nozzles is reduced, and a utilization rate of the nozzles is reduced correspondingly. In addition, the inkjet printing for the pixels with the SBS architecture has a higher requirement on droplet placement accuracy in a scanning direction, and thus there is a risk of color mixing in printing.

### SUMMARY

Accordingly, an embodiment of the present disclosure provides an inkjet printing system, which can reduce the risk of color mixing in printing, can realize fine adjustment for film thickness, and can effectively improve the utilization rate of nozzles.

In order to solve the above problem, technical solutions provided by the present disclosure are as follow.

An inkjet printing system according to an embodiment of the present disclosure includes: an inkjet printing device, comprising a plurality of nozzles, wherein each of the plurality of nozzles has pixel ink; a display substrate, comprising a display region and an under-screen camera region; wherein the plurality of nozzles are arranged above the display substrate; the display substrate comprises a base and a pixel defining layer on a surface of the base, the pixel defining layer is provided with a plurality of first pixel openings and a plurality of second pixel openings, the plurality of first pixel openings are disposed in the display region, and the plurality of second pixel openings are disposed in the under-screen camera region; an opening area of each of the plurality of first pixel openings is greater than an opening area of each of the plurality of second pixel openings; and the plurality of first pixel openings and the plurality of second pixel openings are arranged in rows to define a plurality of pixel rows adjacently arranged; and an ink droplet flow rate control device, connected to the plurality of nozzles and configured to respectively control ink droplet outflow rates of the pixel ink of the plurality of nozzles corresponding to the display region and the under-screen camera region; wherein a number of ink droplets of the pixel ink flowing out from the nozzles corresponding to the first pixel openings is greater than a number of ink droplets of the pixel ink flowing out from the nozzles corresponding to the second pixel openings, in a same time.

In an embodiment of the present disclosure, the pixel defining layer includes a plurality of first pixel defining blocks and a plurality of second pixel defining blocks; each of the plurality of first pixel defining blocks separates the first pixel openings in adjacent pixel rows, and separates the second pixel openings in the adjacent pixel rows; and each of the plurality of second pixel defining blocks separates adjacent first pixel openings, or separates adjacent two second pixel openings, or separates the first pixel opening and the second pixel opening adjacent to the first pixel openings.

In an embodiment of the present disclosure, ink droplets flowing out from the nozzles corresponding to the first pixel defining block and the second pixel defining block fall on the first pixel defining block and the second pixel defining block to flow into the first pixel opening or the second pixel opening.

In an embodiment of the present disclosure, a surface of the pixel defining layer in the display region away from the base is leveled, and the ink droplet overflowing from the second pixel opening is capable of flowing into the first pixel opening.

In an embodiment of the present disclosure, the plurality of nozzles scans in a first direction in a case that inkjet printing is performed; the plurality of first pixel openings and the plurality of second pixel openings are arranged in the first direction, and the plurality of pixel rows are arranged in a second direction perpendicular to the first direction.

In an embodiment of the present disclosure, a first part of the first pixel openings and a first part of the second pixel openings are disposed in a Nth pixel row, a second part of the first pixel openings and a second part of the second pixel openings are disposed in a (N+1)th pixel row, and a third part of the first pixel openings and a third part of the second pixel openings are disposed in a (N+2)th pixel row; wherein N is an integer greater than 0; the Nth pixel row, the (N+1)th pixel row, and the (N+2)th pixel row are sequentially arranged in the second direction; and a color of pixel ink fallen into the first pixel openings and the second pixel openings of the Nth pixel row, a color of pixel ink fallen into the first pixel openings and the second pixel openings of the (N+1)th pixel row, and a color of pixel ink fallen into the first pixel openings and the second pixel openings of the (N+2)th pixel row are different from one another and each are one of red, green and blue.

In an embodiment of the present disclosure, a depth of the first pixel opening in a third direction perpendicular to the first direction is equal to a depth of the second pixel opening in the third direction.

In an embodiment of the present disclosure, a surface of the pixel ink in the first pixel opening away from the base is flushed with a surface of the pixel ink in the second pixel opening away from the base.

In some embodiments of the present disclosure, a number of ink droplets fallen into the first pixel opening and the second pixel opening is an integer or a non-integer.

In an embodiment of the present disclosure, the nozzles all are usable nozzles.

In some embodiments of the present disclosure, in a same pixel row, ink droplets fallen into the display region and ink droplets fallen into the under-screen camera region have a same straight upper level or have different straight upper levels.

In an embodiment of the present disclosure, each of the first pixel defining blocks in the display region includes a first sub pixel block, and a second sub pixel block connected with the first sub pixel block; a surface of the second sub pixel block is smoothly transitionally connected with a surface of the first sub pixel block in the first pixel opening and a surface of the first sub pixel block in the second pixel opening. The inkjet printing system according to an embodiment of the present disclosure, on the basis of pixel openings with a line bank (LB) architecture, reduces the opening area of the second pixel opening in the under-screen camera region, and controls the ink droplet outflow rates of the pixel ink of the nozzles respectively corresponding to the display region and the under-screen camera region by the ink droplet flow rate control device. For the LB architecture, it is formed by printing the sub-pixel with same color in the bank in line manner during processing the display substrate, for example, R/G/B sub-pixels are printed respectively in the respective line. When inkjet printing is performed by the inkjet printing system according to the embodiments of the present disclosure, the nozzles corresponding to the pixel defining layer can also be used, as such, the ink droplets in the nozzles corresponding to the pixel defining layer can flow into the first pixel opening or second pixel opening adjacent thereto owing to a leveling property of the ink droplets in the pixel openings with the LB structure. Thus, not only the utilization rate of the nozzles can be effectively improved, but also fine adjustment for film thickness can be achieved. Since the ink droplets in the pixel openings with the LB architecture have the leveling property, the numbers of ink droplets of the pixel ink of the nozzles respectively corresponding to the display region and the under-screen camera region of the inkjet printing system, according to the embodiments of the present disclosure, can be controlled respectively, there is no special requirement for the S_Main/S_Sub and the placement accuracy of ink droplets in the scanning direction, which can fully meet a transmittance required for under-screen imaging and reduce the risk of color mixing in printing.

### BRIEF DESCRIPTION OF THE DRAWINGS

In order to more clearly illustrate technical solutions in embodiments of the present disclosure, drawings used in the description of the embodiments will be briefly introduced below. Apparently, the drawings in the following description are only some embodiments of the present disclosure, and for those skilled in the art, other drawings can be obtained according to these illustrated drawings without creative work.

FIG. 1 is a schematic block diagram of an inkjet printing system according to some embodiments of the present disclosure.

FIG. 2 is a schematic top view of a display substrate shown in FIG. 1.

FIG. 3 shows a schematic top view of a base and a pixel defining layer of the display substrate shown in FIG. 2, wherein nozzles of an inkjet printing device are shown.

FIG. 4 is a schematic diagram showing nozzles of the inkjet printing device shown in FIG. 3, and a base and a pixel defining layer of a display substrate with ink droplets.

FIG. 5 is a schematic view of a distribution of the ink droplets shown in FIG. 4 in a scanning direction (a first direction).

### DETAILED DESCRIPTION OF THE EMBODIMENTS

Technical solutions in embodiments of the present disclosure will be clearly and completely described below with reference to the accompanying drawings in the embodiment of the present disclosure. Apparently, the described embodiments are merely some of embodiments of the present disclosure, not all of embodiments of the present disclosure. Based on the described embodiments in the present disclosure, all other embodiments obtained by those skilled in the art without making creative efforts belong to the scope of protection of the present disclosure.

In the description of the present disclosure, it should be understood that, orientations or positional relationships indicated by terms such as “top” and “down” are based on orientations or positional relationships shown in the accompanying drawings, and are intended only to facilitate the description of the present disclosure and to simplify the description, not to indicate or imply that a device or an element referred to must have a particular orientation, be constructed and operated in a particular orientation, and is therefore not to be construed as limiting the present disclosure. Furthermore, terms “first” and “second” are used for descriptive purposes only and are not to be construed as indicating or implying relative importance or as implying the number of a technical feature as indicated. Thus, the feature defined by “first” and “second” may be explicitly or implicitly defined to include one or more of the stated features. In the description of the present disclosure, “a plurality of” means two or more, unless specifically defined otherwise.

The present disclosure may repeatedly use reference numerals and/or reference letters in different examples, such repetition being for purposes of simplicity and clarity, and not being indicative of relationships among various embodiments and/or arrangements discussed.

The present disclosure aims to solve the technical problems that the existing ink-jet printing system has the risk of color mixing in printing, cannot realize fine adjustment for film thickness, and has low nozzle utilization rate during inkjet printing. On a basis of pixel openings with a LB architecture, the present disclosure reduces an opening area of a second pixel opening in an under-screen camera region, and controls ink droplet outflow rates of pixel ink of nozzles respectively corresponding to a display region and the under-screen camera region by a ink droplet flow rate control device, thereby reducing the risk of color mixing in printing, realizing fine adjustment for film thickness, and effectively improving the utilization rate of nozzles.

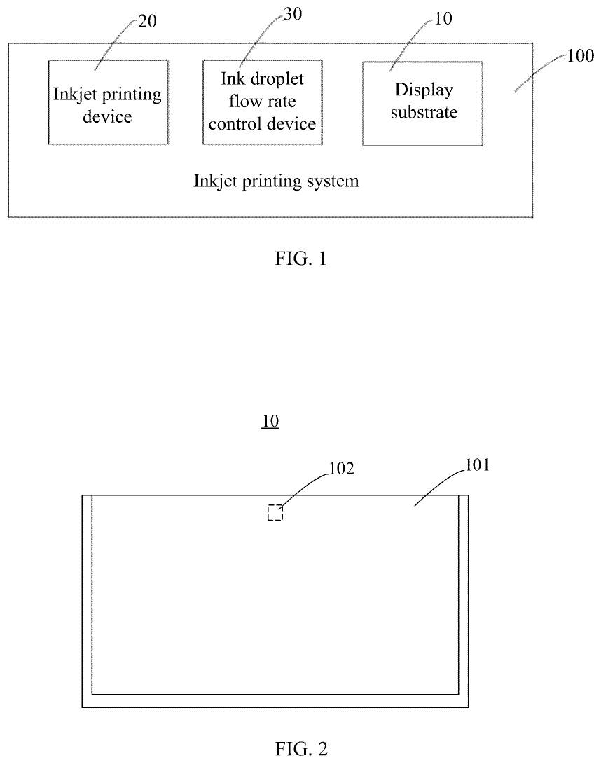

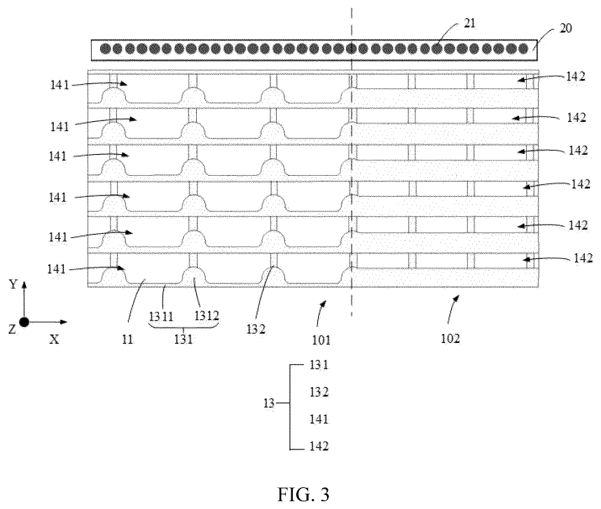

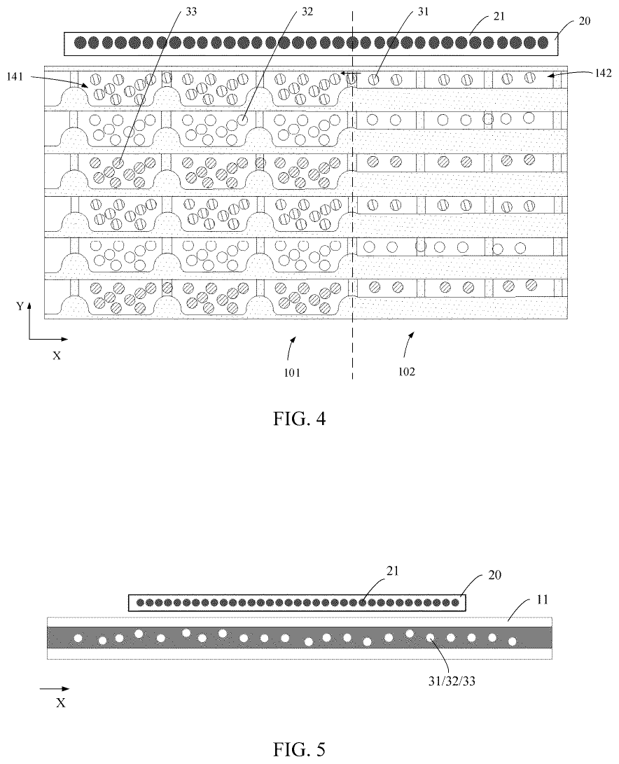

Referring to FIG. 1 through FIG. 5, an embodiment of the present disclosure provides an inkjet printing system 100. The inkjet printing system 100 includes a display substrate 10, an inkjet printing device 20, and an ink droplet flow rate control device 30. The inkjet printing device 20 includes a plurality of nozzles 21, and the nozzles 21 have pixel ink therein. The display substrate 10 includes a display region 101 and an under-screen camera region 102. The nozzles 21 are arranged above the display substrate 10. The display substrate 10 includes a base 11, and a pixel defining layer 13 arranged on a surface of the base 11. The pixel defining layer 13 is disposed with first pixel a plurality of openings 141 and a plurality of second pixel openings 142. The first pixel openings 141 are arranged in the display region 101, and the second pixel openings 142 are arranged in the under-screen camera region 102. An opening area of each of the first pixel openings 141 is greater than an opening area of each of the second pixel openings 142. The first pixel openings 141 and the second pixel openings 142 are arranged in rows to form pixel rows adjacently arranged. The ink droplet flow rate control device 30 is connected to the nozzles 21 and configured to control ink droplet outflow rates of the pixel ink of the nozzles 21 respectively corresponding to the display region 101 and the under-screen camera region 102. Moreover, in a same time, the number of ink droplets of the pixel ink flowing out from the nozzles corresponding to the first pixel opening 141 is greater than the number of ink droplets of the pixel ink flowing out from the nozzles corresponding to the second pixel opening 142.

The inkjet printing system according to an embodiment of the present disclosure, on the basis of pixel openings with the LB architecture, reduces the opening area of the second pixel opening in the under-screen camera region, and controls the ink droplet outflow rates of the pixel ink of the nozzles respectively corresponding to the display region and the under-screen camera region by the ink droplet flow rate control device. When inkjet printing is performed by the inkjet printing system according to the embodiments of the present disclosure, the nozzles corresponding to the pixel defining layer can also be used, as such, the ink droplets in the nozzles corresponding to the pixel defining layer can flow into the first pixel opening or second pixel opening adjacent thereto owing to a leveling property of the ink droplets in the pixel openings with the LB structure. Thus, not only the utilization rate of the nozzles can be effectively improved, but also fine adjustment for film thickness can be achieved. Since the ink droplets in the pixel openings with the LB architecture have the leveling property, the numbers of ink droplets of the pixel ink of the nozzles respectively corresponding to the display region and the under-screen camera region of the inkjet printing system, according to the embodiments of the present disclosure, can be controlled respectively, there is no special requirement for the S_Main/S_Sub and the placement accuracy of ink droplets in the scanning direction, which can fully meet a transmittance required for under-screen imaging and reduce the risk of color mixing in printing.

In an embodiment of the present disclosure, the nozzles 21 scan in a first direction X when defining inkjet printing, the first pixel openings 141 and the second pixel openings 142 are arranged in the first direction X, and the pixel rows are arranged in a second direction Y perpendicular to the first direction X.

In an embodiment of the present disclosure, the pixel defining layer 13 includes a plurality of first pixel defining blocks 131 and a plurality of second pixel defining blocks 132. Each of the first pixel defining blocks 131 separates the first pixel openings 141 located in adjacent two of the pixel rows, and separates the second pixel openings 142 located in the adjacent two of the pixel rows. Each of the second pixel defining blocks 132 separates adjacent two of the first pixel openings 141, or separates adjacent two of the second pixel openings 142, or separates one of the first pixel openings 141 and one of the second pixel openings 142 adjacent to the one of the first pixel openings 141.

In an embodiment of the present disclosure, a part of the first pixel openings 141 and a part of the second pixel openings 142 are located in a Nth pixel row, another part of the first pixel openings 141 and another part of the second pixel openings 142 are located in a (N+1)th pixel row, and yet another part of the first pixel openings 141 and yet another part of the second pixel openings 142 are located in a (N+2)th pixel row; wherein N is an integer greater than 0. The Nth pixel row, the (N+1)th pixel row, and the (N+2)th pixel row are sequentially arranged in the second direction Y. A color of ink droplets 31 fallen into the first pixel openings 141 and the second pixel openings 142 of the Nth pixel row, a color of ink droplets 32 fallen into the first pixel openings 141 and the second pixel openings 142 of the (N+1)th pixel row, and a color of ink droplets 33 fallen into the first pixel openings 141 and the second pixel openings 142 of the (N+2)th pixel row are different from one another, and each are one of red, green, blue and so on.

In an embodiment of the present disclosure, the Nth pixel row, the (N+1)th pixel row, and the (N+2)th pixel row form one pixel opening unit; and the display substrate may include a plurality of the pixel opening units sequentially arranged in the second direction. In the present embodiment, the display substrate includes two pixel opening units, each the pixel opening unit includes a first pixel row, a second pixel row, and a third pixel row sequentially arranged in the second direction Y. The third pixel row of one pixel opening unit is adjacent to the first pixel row of the adjacent pixel opening unit. Colors of ink droplets respectively in the first pixel row, the second pixel row and the third pixel row are different ones of red, green and blue.

The number of the pixel rows in each the pixel opening unit is not limited to 3. The color of ink droplets in each pixel row is also not limited to red, green or blue, and can be set according to a pixel arrangement of an OLED display panel.

In an embodiment of the present disclosure, ink droplets flowing out from the nozzles 21 corresponding to the first pixel defining block 131 and the second pixel defining block 132 fall on the first pixel defining block 131 and the second pixel defining block 132, and are capable of flowing into the first pixel opening 141 or the second pixel opening 142 adjacent to the first pixel defining block 131 and/or the second pixel defining block 132.

In an embodiment of the present disclosure, each first pixel defining block 131 in the display region 101 includes a first sub pixel block 1311 extending in the first direction X, and a second sub pixel block 1312 extending in the second direction Y and connected with the first sub pixel block 1311. For the second pixel defining block 132 in the display region 101, one end of the second pixel defining block 132 is connected to one the first sub pixel block 1311 in a first pixel row, and the other end of the second pixel defining block 132 is connected to the second sub pixel block 1312 of the first pixel defining block 131 in a second pixel row adjacent to the first pixel row. Two ends of the second pixel defining block 132 in the under-screen camera region 102 are connected to two first pixel defining blocks 131 in different pixel rows, respectively.

In an embodiment, a width in the second direction Y of the first sub pixel block 1311 in the under-screen camera region 102 is greater than a width in the second direction Y of the first sub pixel block 1311 in the display region 101.

In an embodiment of the present disclosure, the first sub pixel block 1311 in the under-screen camera region 102 is connected with the first sub pixel block 1311 and the second sub pixel block 1312 both in the display region 101.

In an embodiment of the present disclosure, the first sub pixel block 1311 and the second sub pixel block 1312 are integrally formed, the first sub pixel block 1311 in the under-screen camera region 102 and the first sub pixel block 1311 and the second sub pixel block 1312 both in the display region 101 are integrally formed.

In an embodiment of the present disclosure, a surface of the second sub pixel block 1312 is smoothly and transitionally connected with a surface of the first sub pixel block 1311 away from the base 111. In an embodiment, a surface of the second sub pixel block 1312 is smoothly and transitionally connected with a surface of the first sub pixel block 1311 in the first pixel opening 141 and a surface of the first sub pixel block 1311 the second pixel opening 142. In such way, it is advantageous for ink droplets fallen on the first sub pixel block 1311 and the second sub pixel block 1312 to flow into the first pixel opening 141 and the second pixel opening 142.

In an embodiment, the second sub pixel block 1312 is semicircular. In other embodiments, the shape of the second sub pixel block 1312 is not limited to be semicircular, and may be other shape instead.

In an embodiment of the present disclosure, a surface of the pixel defining layer 13 in the display region 101 away from the base 11 is leveled, and the ink droplet overflowing from the second pixel opening 142 is capable of flowing into the first pixel opening 141.

In an embodiment of the present disclosure, a depth of the first pixel opening 141 in a third direction Z perpendicular to the first direction X is equal to a depth of the second pixel opening 142 in the third direction Z.

In an embodiment of the present disclosure, a surface of the pixel ink in the first pixel opening 141 that faces away from the base 11 is flushed with a surface of the pixel ink in the second pixel opening 142 that faces away from the base 11.

In an embodiment of the present disclosure, a number of ink droplets fallen into the first pixel opening 141 and/or the second pixel opening 142 is an integer, or is a non-integer instead.

In an embodiment of the present disclosure, the nozzles 21 all are usable nozzles.

In an embodiment of the present disclosure, in a same the pixel row, the ink droplets fallen into the display region 101 and the ink droplets fallen into the under-screen camera region 102 have a same straight upper level, or have different straight upper levels.

The inkjet printing system according to the embodiments of the present disclosure, on the basis of pixel openings with the LB architecture, reduces the opening area of the second pixel opening in the under-screen camera region, and controls the ink droplet outflow rates of the pixel ink of the nozzles respectively corresponding to the display region and the under-screen camera region by the ink droplet flow rate control device. When inkjet printing is performed by the inkjet printing system according to the embodiments of the present disclosure, the nozzles corresponding to the pixel defining layer can also be used, as such the ink droplets in the nozzles corresponding to the pixel defining layer can flow into the first pixel opening or second pixel opening adjacent thereto owing to a leveling property of the ink droplets in the pixel openings with the LB structure. Thus, only the utilization rate of the nozzles can be effectively improved, but also fine adjustment for film thickness can be achieved. Since the ink droplets in the pixel openings with the LB architecture have the leveling property, the numbers of ink droplets of the pixel ink of the nozzles respectively corresponding to the display region and the under-screen camera region of the inkjet printing system according to the embodiments of the present disclosure can be controlled respectively, there is no special requirement for the S_Main/S_Sub and the placement accuracy of ink droplets in the scanning direction, which can fully meet a transmittance required for under-screen imaging and reduce the risk of color mixing in printing.

The foregoing provides a detailed description to the inkjet printing system according to embodiments of the present disclosure, and in this specification, specific examples are used to describe the principle and embodiments of the present disclosure, and the description of the above embodiments is only used to help understand the technical solutions and the core idea of the present disclosure. Those skilled in the art should understand that, the technical solutions described in the foregoing embodiments can still be modified, or some of the technical features thereof can be equivalently replaced, and such modifications or replacements do not cause the essence of the corresponding technical solutions to deviate from the scope of the technical solutions of the embodiments of the present disclosure.

What is claimed is:

1. An inkjet printing system, comprising:
an inkjet printing device, comprising a plurality of nozzles, wherein each of the plurality of nozzles has pixel ink;
a display substrate, comprising a display region and an under-screen camera region; wherein the plurality of nozzles are arranged above the display substrate; the display substrate comprises a base and a pixel defining layer on a surface of the base, the pixel defining layer is provided with a plurality of first pixel openings and a plurality of second pixel openings, the plurality of first pixel openings are disposed in the display region, and the plurality of second pixel openings are disposed in the under-screen camera region; an opening area of each of the plurality of first pixel openings is greater than an opening area of each of the plurality of second pixel openings; and the plurality of first pixel openings and the plurality of second pixel openings are arranged in rows to define a plurality of pixel rows adjacently arranged; and
an ink droplet flow rate control device, connected to the plurality of nozzles and configured to respectively control ink droplet outflow rates of the pixel ink of the plurality of nozzles corresponding to the display region and the under-screen camera region;
wherein a number of ink droplets of the pixel ink flowing out from the nozzles corresponding to the first pixel openings is greater than a number of ink droplets of the pixel ink flowing out from the nozzles corresponding to the second pixel openings, in a same time.

2. The inkjet printing system of claim 1, wherein the pixel defining layer comprises a plurality of first pixel defining blocks and a plurality of second pixel defining blocks;
wherein each of the plurality of first pixel defining blocks separates the first pixel openings in adjacent pixel rows, and separates the second pixel openings in the adjacent pixel rows;
wherein each of the plurality of second pixel defining blocks separates adjacent first pixel openings, or separates adjacent two second pixel openings, or separates the first pixel opening and the second pixel opening adjacent to the first pixel openings.

3. The inkjet printing system of claim 2, wherein ink droplets flowing out from the nozzles corresponding to the first pixel defining block and the second pixel defining block fall on the first pixel defining block and the second pixel defining block to flow into the first pixel opening or the second pixel opening;
wherein the first pixel defining block in the display region comprises a first sub pixel block, and a second sub pixel block connected with the first sub pixel block; a surface of the second sub pixel block is smoothly transitionally connected with a surface of the first sub pixel block in the first pixel opening and a surface of the first sub pixel block in the second pixel opening.

4. The inkjet printing system of claim 1, wherein a surface of the pixel defining layer in the display region away from the base is leveled, and the ink droplet overflowing from the second pixel opening is capable of flowing into the first pixel opening.

5. The inkjet printing system of claim 1, wherein the plurality of nozzles scans in a first direction in a case that inkjet printing is performed; the plurality of first pixel openings and the plurality of second pixel openings are arranged in the first direction, and the plurality of pixel rows are arranged in a second direction perpendicular to the first direction.

6. The inkjet printing system of claim 5, wherein a first part of the first pixel openings and a first part of the second pixel openings are disposed in a Nth pixel row, a second part of the first pixel openings and a second part of the second pixel openings are disposed in a (N+1)th pixel row, and a third part of the first pixel openings and a third part of the second pixel openings are disposed in a (N+2)th pixel row; wherein N is an integer greater than 0;
wherein the Nth pixel row, the (N+1)th pixel row, and the (N+2)th pixel row are sequentially arranged in the second direction;
wherein a color of pixel ink fallen into the first pixel openings and the second pixel openings of the Nth pixel row, a color of pixel ink fallen into the first pixel openings and the second pixel openings of the (N+1)th pixel row, and a color of pixel ink fallen into the first pixel openings and the second pixel openings of the (N+2)th pixel row are different from one another and each are one of red, green and blue.

7. The inkjet printing system of claim 1, wherein a depth of the first pixel opening in a third direction perpendicular to the first direction is equal to a depth of the second pixel opening in the third direction.

8. The inkjet printing system of claim 7, wherein a surface of the pixel ink in the first pixel opening away from the base is flushed with a surface of the pixel ink in the second pixel opening away from the base.

9. The inkjet printing system of claim 1, wherein a number of ink droplets fallen into the first pixel opening and the second pixel opening is an integer or a non-integer.

10. The inkjet printing system of claim 1, wherein the plurality of nozzles all are usable nozzles; and
wherein in a same pixel row, ink droplets fallen into the display region and ink droplets fallen into the under-screen camera region have a same straight upper level.

11. The inkjet printing system of claim 1, wherein the plurality of nozzles all are usable nozzles; and in a same pixel row, ink droplets fallen into the display region and ink droplets fallen into the under-screen camera region have different straight upper levels.
